(19) United States
(12) Patent Application Publication
(10) Pub. No.: US 2026/0152383 A1
(43) Pub. Date: Jun. 4, 2026

(54) High-Frequency BIAXIAL Bi-Resonant Microelectromechanical Mirror Structure

(71) Applicant: STMicroelectronics International N.V., Geneva (CH)

(72) Inventors: Giacomo FERRARI, Broni (IT); Roberto CARMINATI, Piancogno (IT); Massimiliano MERLI, Stradella (IT)

(73) Assignee: STMicroelectronics International N.V., Geneva (CH)

(21) Appl. No.: 18/821,194

(22) Filed: Aug. 30, 2024

(30) Foreign Application Priority Data
Aug. 31, 2023 (IT) 102023000017949

(51) Int. Cl. B81B 3/00; G02B 26/08; G02B 26/10

(52) U.S. Cl. CPC B81B 3/0062; G02B 26/0858; G02B 26/101; B81B 2201/042; B81B 2203/0154; B81B 2203/0307; B81B 2203/058

(57) ABSTRACT

A microelectromechanical mirror structure includes a mobile mass movable around a first rotation axis, with a first resonant scanning mode at a lower resonance frequency, and around a second rotation axis, with a second resonant scanning mode at a higher resonance frequency greater than the lower resonance frequency. The structure includes a first frame surrounding and elastically coupled to the mobile mass by a first and a second torsional elastic elements aligned along the second rotation axis. The structure includes a second frame extending externally to the first frame and elastically coupled to the first frame by a third and a fourth torsional elastic elements aligned along the first scanning axis. First piezoelectric actuators are on the second frame operable to actuate the first resonant scanning mode and an actuation structure external to the second frame and carrying second piezoelectric actuators, operable to actuate the second resonant scanning mode.

### BACKGROUND

### Technical Field

The present disclosure relates to a high-frequency biaxial bi-resonant microelectromechanical (made using MEMS-Micro-Electro-Mechanical System-technology) mirror structure.

### Description of the Related Art

Microelectromechanical structures (hereinafter “MEMS structures”) are known including a mobile mass carrying a reflective surface, so-called “mirror” surface, formed starting from a body of semiconductor material, generally silicon, and elastically supported above a cavity so as to be tiltable in a desired manner.

MEMS mirror structures are used, for example, in Laser Beam Scanning (LBS) displays, for example for virtual reality or augmented reality applications, or in LIDAR (Laser Imaging Detection and Ranging) devices.

In general, MEMS mirror structures are operated to direct light radiation beams generated by a light source, for example of a laser type, in desired patterns for their projection at a distance.

Typically, a deviation of the light beam along two axes is beneficial, which may be provided by two uniaxial-type MEMS mirror structures, or by a single biaxial-type MEMS mirror structure. In the case of a biaxial-type MEMS structure, the mobile mass is operated to rotate around a first and a second rotation axis, orthogonal to each other.

In particular, for generating a so-called “Lissajous” scanning pattern, both rotations of the mobile mass, around the first and the second rotation axes, are performed with a resonant movement, i.e., with a periodic or quasi-periodic oscillation at a frequency proximate to the mechanical resonance frequency of the mirror structure with respect to the aforementioned rotation axes.

MEMS mirror structures operating in resonance around both rotation axes are generally referred to as bi-resonant structures.

The resonant movement advantageously allows maximizing the angular distance covered by the mobile mass during each oscillation and therefore maximizing the dimension of the portion of space subject to scanning with a same size of the micromechanical structure.

In the case of biaxial and bi-resonant scanning, it would be beneficial to obtain high values of resonance frequency around both scanning axes, while obtaining values of these resonance frequencies separate and distinct from each other.

Known biaxial micromirror structures allow high values of resonance frequency to be obtained, but with values of resonance frequency around the two rotation axes being very similar to each other (and a resulting limitation in the achievable opening angle or “field of view”).

A separation of the values of the resonance frequency (between a higher resonance frequency around a “fast” scanning axis and a lower resonance frequency around a “slow” scanning axis) is currently possible, but only with limited values for the lower resonance frequency.

Possible examples of known-type MEMS mirror structures are described for example in:
Hofmann, Ulrich & Janes, Joachim & Quenzer, Hans. (2012), High-Q MEMS resonators for laser beam scanning displays, Micromachines, 3, 509-528;
Gu-Stoppel, Shanshan & Quenzer, Hans & Benecke, W. (2015), Design, fabrication and characterization of piezoelectrically actuated gimbal-mounted 2D micromirrors, 851-854.

### SUMMARY

Embodiments of the present disclosure overcome, at least in part, the limitations of known-type structures.

In one embodiment, a biaxial bi-resonant microelectromechanical mirror structure is provided.

In one embodiment, a microelectromechanical mirror structure includes a mobile mass, configured to be actuated around a first rotation axis, with a first resonant scanning mode at a first resonance frequency around a second rotation axis, with a second resonant scanning mode at a second resonance frequency greater than the first resonance frequency. The structure includes a first frame suspended and surrounding the mobile mass and elastically coupled to the mobile mass by a first torsional elastic element and a second torsional elastic element aligned on opposite sides of the mobile mass along the second rotation axis and a second frame suspended and arranged externally around the first frame and elastically coupled to the first frame by a third torsional elastic element and a fourth torsional elastic element aligned along the first rotation axis. The structure includes first piezoelectric actuators, arranged on the second frame and configured to actuate the first resonant scanning mode of the mobile mass and an actuation structure arranged externally to the second frame and carrying second piezoelectric actuators configured to actuate the second resonant scanning mode of the mobile mass.

In one embodiment, a method includes activating, with first piezoelectric actuators, a first resonant scanning mode of a mobile mass around a first axis. The mobile mass is surrounded by a first frame suspended and coupled to the mobile mass by a first torsional elastic element and a second torsional elastic element arranged along a second axis perpendicular to the first axis. A second frame is suspended and surrounds the second frame and connected to the first frame by a third torsional elastic element and a fourth torsional elastic element arranged along the first axis, the first piezoelectric actuators being on the second frame. The method includes activating, with second piezoelectric actuators on an actuation structure arranged externally to the second frame, a second resonant scanning mode of the mobile mass around the second axis. The first resonant scanning mode has a first scanning frequency and the second resonant scanning mode has a second scanning frequency higher than the first resonance frequency.

In one embodiment, a device includes a suspended mobile mass having a mirror surface, a suspended first frame surrounding the mobile mass and coupled to the mobile mass by first torsional elastic elements arranged along a first axis, and a suspended second frame surrounding the mobile mass and coupled to the mobile mass by second torsional elastic elements arranged along a second axis perpendicular to the first axis and including first piezoelectric actuators. The device includes an actuation structure external to the second frame and including second piezoelectric actuators and an actuation transfer structure interposed between the actuation structure and the second frame.

### BRIEF DESCRIPTION OF THE SEVERAL VIEWS OF THE DRAWINGS

For a better understanding of the present disclosure, a preferred embodiment thereof is now described, purely by way of non-limiting example and with reference to the attached drawings, wherein:

FIG. 1 shows a schematic plan view of a MEMS mirror structure, according to an embodiment of the present disclosure;

FIGS. 2A-2B schematically show resonant scanning modes of the structure of FIG. 1, around a slow scanning axis and, respectively, around a fast scanning axis;

FIG. 3 schematically shows a resonant scanning mode around a fast scanning axis, in the case of a variant embodiment of the structure of FIG. 1;

FIG. 4 shows a schematic plan view of a MEMS mirror structure, according to a further embodiment of the present disclosure; and

FIGS. 5A-5B schematically show resonant scanning modes of the structure of FIG. 4, around a slow scanning axis and, respectively, around a fast scanning axis.

### DETAILED DESCRIPTION

One embodiment of the present disclosure provides a biaxial MEMS mirror structure, with bi-resonant actuation, at a higher resonance frequency, of greater value, around a first scanning axis, defined as fast scanning axis, and at a lower resonance frequency, of smaller value, around a second scanning axis, defined as slow scanning axis.

Thanks to the configuration of the MEMS mirror structure, which will now be described in detail, both resonance frequencies have high values, in particular higher than 10 kHz, for example comprised between 10 kHz and 20 kHz, and are separated and distinct from each other by a wide frequency range, for example of at least 10 kHz. In particular, the ratio between the (higher and lower) resonance frequencies may be comprised between 1.5 and 3.

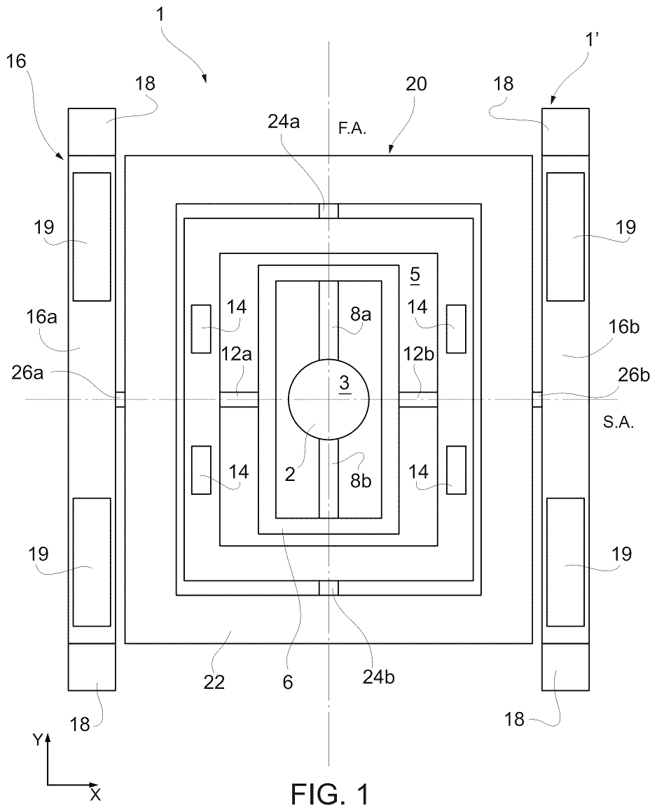

As shown in FIG. 1, the MEMS mirror structure, indicated as a whole by 1, is formed in a die 1′ of semiconductor material, in particular silicon.

The MEMS mirror structure 1 includes a mobile mass 2, tiltable by piezoelectric actuation (as will be described in detail below), which carries a reflective material surface 3, so-called mirror surface, at the top; in the example, the mobile mass 2 has a substantially circular shape in a horizontal plane xy of main extension of the same MEMS mirror structure 1, formed by a first and a second horizontal axes x, y, orthogonal to each other.

The mobile mass 2 is suspended in a cavity 5 and is arranged within a first frame 6, having for example a substantially rectangular extension elongated along the second horizontal axis y; the mobile mass 2 is elastically coupled to the first frame 6 by a first and a second torsional elastic elements 8a, 8b (in a known manner, here not illustrated, this cavity 5 is at least partly formed in an underlying support substrate, to which the die 1′ is coupled to form a corresponding package).

According to an aspect of the present disclosure, the first frame 6 is configured to behave as an elastic element, having major sides made by elongated beams with a suitable aspect ratio, between length and width (considered in the horizontal plane xy); for example, such aspect ratio is greater than or equal to 6:1, preferably greater than or equal to 10:1.

The aforementioned first and second torsional elastic elements 8a, 8b extend on opposite sides of the mobile mass 2, between the same mobile mass 2 and a respective (minor) side of the first frame 6.

The extension axis defined by the first and the second torsional elastic elements 8a, 8b, aligned and parallel to the second horizontal axis y, is the fast scanning axis (Fast Axis, F.A.) of the MEMS mirror structure 1, around which movement occurs at the higher resonance frequency, for example with a value higher than 20 KHz.

The MEMS mirror structure 1 has a symmetrical configuration with respect to the aforementioned fast scanning axis.

The MEMS mirror structure I also includes a second frame 10, which extends externally to the first frame 6, surrounding it in the horizontal plane xy, for example also having a substantially rectangular shape in the horizontal plane xy.

The second frame 10 is arranged suspended in the cavity 5, elastically coupled to the first frame 6 by a third and a fourth torsional elastic elements 12a, 12b, which extend between facing sides (in the example, respective major sides) of the same first and second frames 6, 10.

The extension axis defined by the aforementioned third and fourth torsional elastic elements 12a, 12b, aligned and parallel to the first horizontal axis x, is the slow scanning axis (Slow Axis, S.A.) of the MEMS mirror structure 1 (orthogonal to the aforementioned fast scanning axis), around which movement occurs at the lower resonance frequency, of smaller value and well separated with respect to the higher resonance frequency, for example greater than 10 KHz and separated from the higher resonance frequency by an interval greater than 10 KHz.

The MEMS mirror structure 1 has a symmetrical configuration with respect to the aforementioned slow scanning axis.

First piezoelectric actuators 14, formed by respective regions of piezoelectric material, for example PZT (Lead Zirconate Titanate), arranged on the second frame 10, are operable to actuate the rotation mode of the mobile mass 2 around the slow scanning axis.

In particular, a first pair of the aforementioned first piezoelectric actuators 14, arranged on respective opposite (major) sides of the second frame 10, on a first side of the slow scanning axis, are biased, during operation, at a same first biasing voltage; similarly, a second pair of the aforementioned first piezoelectric actuators 14, arranged on the opposite side of the slow scanning axis (specularly to the actuators of the first pair), are biased, during operation, at a respective same second biasing voltage (different from the aforementioned first biasing voltage).

The MEMS mirror structure 1 also includes an actuation structure 16, formed by a first and a second actuation arms 16a, 16b, arranged in a suspended manner externally to the second frame 10, on opposite sides with respect to the fast scanning axis (Fast Axis, F.A.), with extension along the second horizontal axis y.

Each of the aforementioned first and second actuation arms 16a, 16b has both ends coupled to respective anchors 18 of the MEMS mirror structure 1, fixed during operation of the same MEMS mirror structure 1. These anchors 18 are for example integral with the support substrate to which the die 1′ is coupled (these anchors 18 being made by vertical elements which extend between the respective first or second actuation arm 16a, 16b and the aforementioned support substrate).

Second piezoelectric actuators 19, formed by respective regions of piezoelectric material, for example PZT (Lead Zirconate Titanate), arranged on the aforementioned first and second actuation arms 16a, 16b, are operable to actuate the rotation mode of the mobile mass 2 around the fast scanning axis.

In particular, a first pair of the aforementioned second piezoelectric actuators 19, arranged on the first actuation arm 16a, on a first side of the fast scanning axis, are biased, during operation, to a same first biasing voltage; similarly, a second pair of the aforementioned second piezoelectric actuators 19, arranged on the second actuation arm 16b, on the opposite side of the fast scanning axis (specularly to the actuators of the first pair), are biased, during operation, to a respective same second biasing voltage (different from the aforementioned first biasing voltage).

The MEMS mirror structure 1 also includes an actuation transfer structure 20, interposed between the aforementioned first and second actuation arms 16a, 16b and the second frame 10 and configured to transfer the driving force generated by the aforementioned second piezoelectric actuators 19 to the second frame 10.

In particular, in the embodiment shown in FIG. 1, this actuation transfer structure 20 is made by a third frame 22 which extends externally to the second frame 10, surrounding it in the horizontal plane xy, for example also having a substantially rectangular, or square, extension in the horizontal plane xy.

The third frame 22 is arranged in a suspended configuration, elastically coupled to the second frame 10 by a fifth and a sixth torsional elastic elements 24a, 24b, which extend between facing sides of the same first and second frames 6, 10 (in the example between the corresponding minor sides, the aforementioned fifth and sixth torsional elastic elements 24a, 24b being aligned along the fast scanning axis, on opposite sides of the mobile mass 2).

The third frame 22 is also coupled to the first and second actuation arms 16a, 16b, respectively by a first and a second coupling elastic elements 26a, 26b, arranged at the slow scanning axis and aligned along the same slow scanning axis; in particular, these first and second coupling elastic elements 26a, 26b are configured to be yielding to both torsion, around the slow scanning axis, and bending, outside of the horizontal plane xy.

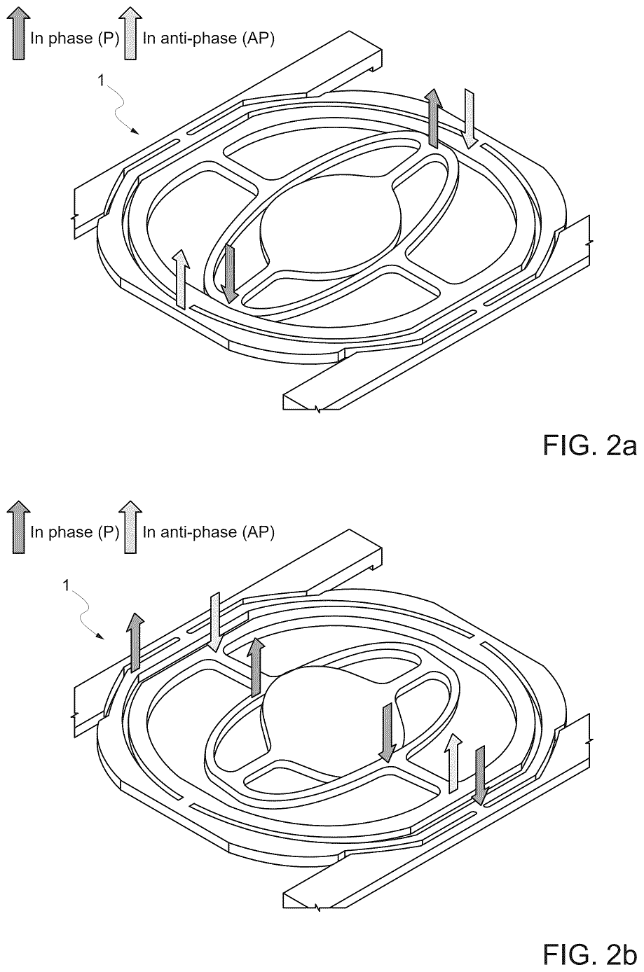

During operation, and as shown in FIG. 2A (where the arrows indicate the phase or anti-phase movements, considering as a reference the desired movement of the mobile mass 2), actuation of the first piezoelectric actuators 14 placed on the second frame 10 determines the rotation of the mobile mass 2 of the MEMS mirror structure 1 around the slow scanning axis, according to a slow scanning mode (at the lower resonance frequency).

In particular, during the aforementioned slow scanning mode, the second frame 10 behaves as a rigid body and is subject, due to actuation of the aforementioned first piezoelectric actuators 14, to a rotation movement around the slow scanning axis. The actuation transfer structure 20, in the example made by the third frame 22, is integral with the second frame 10 in this rotation movement.

The actuation of the aforementioned second frame 10 excites an anti-phase rotation movement of the first frame 6, which integrally drags the mobile mass 2 determining its desired rotation movement around the slow scanning axis, at the lower resonance frequency.

In this rotation mode, the second and third frames 10, 22 move in anti-phase with respect to the movement of the mobile mass 2 (and of the first frame 6, integral with the same mobile mass 2, as a single body); conversely, the actuation structure 20 is not involved in this slow scanning mode.

It is highlighted that the presence of the second frame 10 advantageously allows the actuation of a slow scanning mode at a high frequency (for example higher than 10 kHz).

It is also highlighted that the impact of the aforementioned actuation transfer structure 20 (in the example, of the third frame 22) is negligible on the actuation of the slow scanning axis, given that it moves rigidly with the second frame 10 without therefore affecting the rotation mode of the mobile mass 2.

In greater detail, as regards the aforementioned slow scanning mode, the second frame 10 and the third frame 22 jointly have (rotating as a single rigid body) a moment of inertia, which is higher (in particular much higher) than the moment of inertia of the first frame 6.

In particular, according to one aspect of the present disclosure, the following relationship applies:

$${J}_{xx , 2} + {J}_{xx , 3} \geq 3 \cdot {J}_{xx , 1}$$

preferably:

$${J}_{xx , 2} + {J}_{xx , 3} \geq 6 \cdot {J}_{xx , 1}$$

where J_{xx,1} indicates the overall moment of inertia of the first frame 6, of the mobile mass 2 and of the first and second torsional elements 8a, 8b and J_{xx,2}, J_{xx,3} indicate the moments of inertia of the second frame 10 and, respectively, of the third frame 22, around the aforementioned slow scanning axis (coincident with the first horizontal axis x of the horizontal plane xy).

As shown in FIG. 2B, actuation of the second piezoelectric actuators 19 arranged on the first and the second actuation arms 16a, 16b determines the rotation of the mobile mass 2 of the MEMS mirror structure 1 around the fast scanning axis, according to a rapid scanning mode (at the higher resonance frequency).

In particular, the actuation transfer structure 20, in this embodiment being the third frame 22, transfers the actuation torque determined by actuation of the aforementioned second piezoelectric actuators 19 to the second frame 10, causing its rotation movement around the fast scanning axis.

This results in the rotation of the first frame 6, which moves with a rotation movement around the aforementioned fast scanning axis, in anti-phase with respect to the movement of the second frame 10; and furthermore in the desired rotation of the mobile mass 2 around the same fast scanning axis, in phase with the first frame 6.

In particular, as previously indicated, the first frame 6 is configured to behave as an elastic element and transfers the rotation torque to the mobile mass 2 for its rotation around the fast scanning axis.

In essence, and as indicated by the arrows in the aforementioned FIG. 2B, in this rotation mode, the second frame 10 moves in anti-phase with respect to the movement of the mobile mass 2; conversely, the first frame 6 moves in phase with respect to the rotation of the mobile mass 2.

As regards the aforementioned fast scanning mode, the second frame 10 has a higher (in particular much higher) moment of inertia than the moment of inertia of the first frame 6.

In particular, according to one aspect of the preset disclosure, the following relationship applies:

$${J}_{yy , 2} \geq 3 \cdot {J}_{yy , 1}$$

preferably:

$${J}_{yy , 2} \geq 9 \cdot {J}_{yy , 1}$$

where J_{yy,1} indicates the moment of inertia of the first frame 6, of the mobile mass 2 and of the first and second torsional elements 8a, 8b and J_{yy,2} indicates the moment of inertia of the second frame 10, around the aforementioned fast scanning axis (coincident with the second horizontal axis y of the horizontal plane xy).

It is underlined that in the aforementioned fast scanning mode, the actuation transfer structure 20 allows the actuation efficiency to be improved, as it allows a controlled movement to be obtained for the second piezoelectric actuators 19 and optimization of the mechanical work thereof (through reduction of the resistance of the actuation structure 16 to rotation of the other internal elements around the fast scanning axis), compensating the reduction in actuation efficiency caused by the presence of the second frame 10. In other words, this allows the driving voltage to obtain a desired opening angle for the MEMS mirror structure 1 to be reduced and, therefore, the energy consumption to be limited.

The specific movement of the actuation transfer structure 20 (i.e., of the third frame 22) in the fast scanning mode depends on the inertial ratio with respect to the second frame 10, two implementation options being possible in this respect.

In a first implementation, to which the aforementioned FIGS. 1 and 2A-2B refer, the following relationship may be considered:

$${J}_{yy , 3} \geq 0.75 \cdot {J}_{yy , 2}$$

preferably:

$${J}_{y y , 3} \geq {J}_{y y , 2}$$

where J_{yy,3}, J_{yy,2} indicate the moments of inertia of the third frame 22 and, respectively, of the second frame 10 around the aforementioned fast scanning axis (coincident with the second horizontal axis y of the horizontal plane xy).

In this implementation, the third frame 22 moves in phase with respect to the movement of the mobile mass 2 around the fast scanning axis and therefore in anti-phase with respect to the second frame 10.

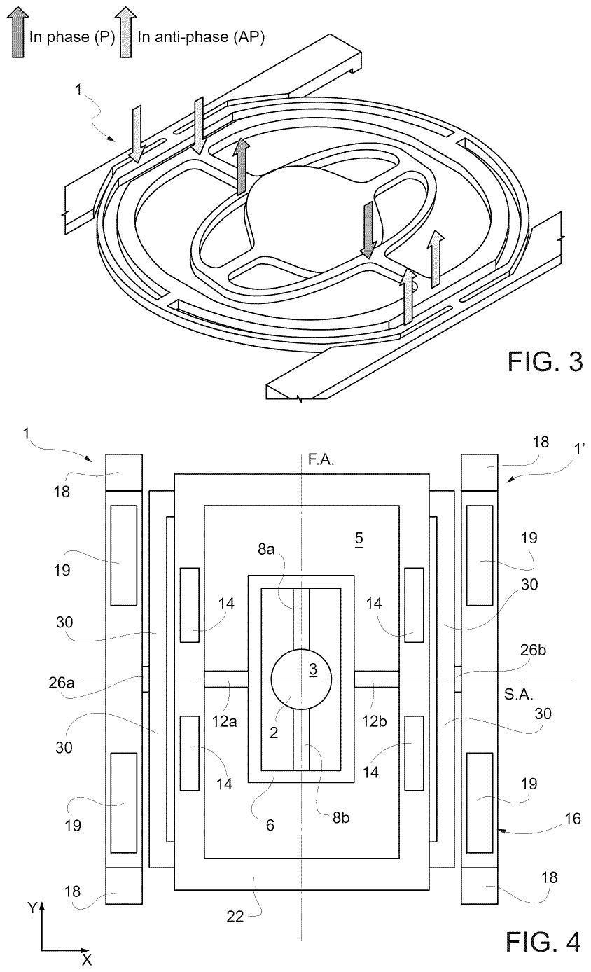

In a second implementation, which is shown in FIG. 3 (which illustrates the fast scanning mode), the following relationship applies:

$${J}_{yy , 3} < 0.75 \cdot {J}_{yy , 2}$$

preferably:

$${J}_{yy , 3} \leq 0.6 \cdot {J}_{yy , 2}$$

In this implementation, in the resonant movement around the fast scanning axis, the third frame 22 moves in anti-phase with respect to the movement of the mobile mass 2, unlike what has been previously described for the first implementation, and therefore in phase with the second frame 10.

Conversely, there are no changes with respect to what has been previously described as regards the resonant movement around the slow scanning axis (which is therefore not illustrated again).

With reference to FIG. 4, a further embodiment of the MEMS mirror structure 1 is now described, which may be considered as a particular case of the aforementioned second implementation (since the same inertial ratio is applied between the second frame 10 and the actuation transfer structure 20).

In detail, in this embodiment, the actuation transfer structure 20 is made by four beam elements 30, arranged externally to the second frame 10, in pairs on opposite sides of the same second frame 10, symmetrically with respect to the fast scanning axis.

These beam elements 30 have an elongated shape along the second horizontal axis y, with an aspect ratio greater than or equal to 4:1 (between their length and their width or cross-section), preferably greater than or equal to 5:1.

The beam elements 30 of each pair are aligned along the second horizontal axis y, facing a respective long or major side of the second frame 10, and have a first common end, arranged at the slow scanning axis and coupled to the first or second actuation arm 16a, 16b by the first or the second coupling elastic element 26a, 26b, and a second end coupled to the respective long side of the second frame 10, distally and on the opposite side with respect to the slow scanning axis.

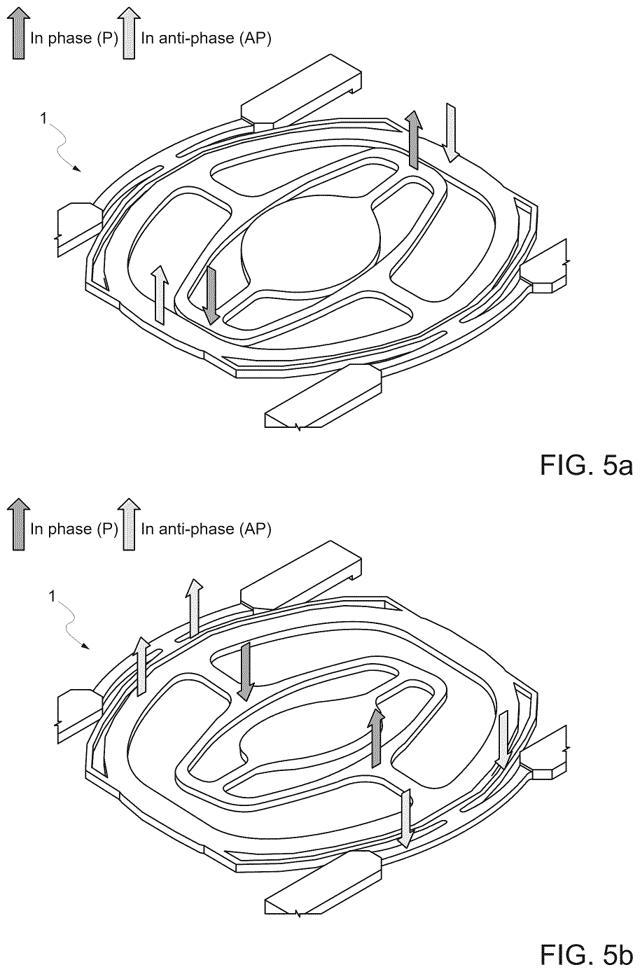

FIGS. 5A and 5B show for completeness the slow and, respectively, fast scanning modes of the MEMS mirror structure 1 in this further embodiment.

The operation of the MEMS mirror structure 1 does not, however, differ from what has been previously described (with particular reference to the aforementioned second implementation of the inertia ratio between actuation transfer structure 20 and second frame 10) and will therefore not be described again in detail.

The advantages of the proposed disclosure are clear from the preceding description.

In any case, it is emphasized that this disclosure allows high resonance frequencies to be obtained for the rotation movements around both, slow and fast, rotation axes with a clear separation between the values of the same resonance frequencies.

The MEMS mirror structure 1 also has a high value of the opening angle or the so-called “field of view,” with a similar energy consumption as compared to known-type structures.

Furthermore, the structure described does not call for substantial changes as regards a corresponding manufacturing process, as compared to similar known-type structures.

Finally, it is clear that modifications and variations may be made to what is described and illustrated herein without thereby departing from the scope of the present disclosure.

For example, it is underlined that the shape of one or more of the elements of the MEMS mirror structure I could vary with respect to what has been described and illustrated, without implying any substantial change to the operation described for the same MEMS mirror structure 1.

In one embodiment, a microelectromechanical mirror structure (1) includes a mobile mass (2), configured to be actuated around a first rotation axis (S.A.), with a first resonant scanning mode at a lower resonance frequency, and around a second rotation axis (F.A.), with a second resonant scanning mode at a higher resonance frequency, greater than the lower resonance frequency; a first frame (6), suspended and surrounding the mobile mass (2), to which it is elastically coupled by a first and a second torsional elastic elements (8a, 8b) aligned, on opposite sides of the mobile mass (2), along the second rotation axis (F.A.); a second frame (10), suspended and arranged externally and around the first frame (6), elastically coupled to the first frame (6) by a third and a fourth torsional elastic elements (12a, 12b), aligned along the first rotation axis (S.A.); first piezoelectric actuators (14), arranged on the second frame (10), operable to actuate the first resonant scanning mode of the mobile mass (2); and an actuation structure (16) arranged externally to the second frame (10) and carrying second piezoelectric actuators (19), operable to actuate the second resonant scanning mode of the mobile mass (2).

In one embodiment, the actuation structure (16) includes a first and a second actuation arms (16a, 16b), arranged externally to the second frame (10), on opposite sides with respect to the second rotation axis (F.A.); each of the first and second actuation arms (16a, 16b) having both ends coupled to anchors (18) of the microelectromechanical mirror structure (1) and carrying a respective pair of the second piezoelectric actuators (19).

In one embodiment, the structure further includes an actuation transfer structure (20), interposed between the actuation structure (16) and the second frame (10) and configured to transfer an actuation force generated by the second piezoelectric actuators (19) to the second frame (10) for actuating the second resonant scanning mode of the mobile mass (2); the actuation transfer structure (20) being elastically coupled to the actuation structure (16) by a first and a second coupling elastic elements (26a, 26b), arranged aligned at the first rotation axis (S.A.).

In one embodiment, the actuation transfer structure (20) is made by a third frame (22), suspended and arranged externally to the second frame (10) and coupled to the second frame (10) by a fifth and a sixth torsional elastic elements (24a, 24b), which extend, aligned along the second rotation axis (F.A.), between facing sides of the first and second frames (6, 10), on opposite sides of the mobile mass (2).

In one embodiment, the actuation transfer structure (20) is made by beam elements (30), suspended and placed externally to the second frame (10), in pairs on opposite sides of the second frame (10); wherein the beam elements (30) of each pair face a respective side of the second frame (10), and have a first common end, arranged at the second rotation axis (S.A.) and coupled to the actuation structure (16) by the first or second coupling elastic element (26a, 26b), and a second end coupled to the respective side of the second frame (10), distally and on the opposite side with respect to the second rotation axis (S.A.).

In one embodiment, the beam elements (30) have an elongated shape, with an aspect ratio greater than or equal to 4:1.

In one embodiment, first frame (6) has major sides made by elongated elements, with an aspect ratio greater than or equal to 6:1.

In one embodiment, the first resonant scanning mode, the second frame (10) is integral with the actuation transfer structure (20) in the rotation around the first rotation axis (S.A.) due to actuation of the first piezoelectric actuators (14); and the first frame (6) is integral with the mobile mass (2) in a rotation, in anti-phase with respect to the second frame (10), around the first rotation axis (S.A.), at the lower resonance frequency.

In one embodiment, the first resonant scanning mode, the second frame (10) and the actuation transfer structure (20) jointly have, as a single rigid body, a higher moment of inertia with respect to the moment of inertia of the first frame (6).

In one embodiment, the following relationship applies:

$${J}_{xx , 2} + {J}_{xx , 3} \geq 3 \cdot {J}_{xx , 1}$$

where J_{xx,1} indicates the overall moment of inertia of the first frame (6), of the mobile mass (2) and of the first and second torsional elements (8a, 8b) and J_{xx,2}, J_{xx,3} indicate the moments of inertia of the second frame (10) and, respectively, of the actuation transfer structure (20), around the first rotation axis (S.A.).

In one embodiment, the second resonant scanning mode, the first frame (6) is configured to have a rotation movement around the second rotation axis (F.A.), in anti-phase with respect to the movement of the second frame (10) and in phase with the mobile mass (2); the first frame (6) being configured to transfer a rotation torque from the second frame (10) to the mobile mass (2) for its rotation around the second rotation axis (F.A.).

In one embodiment, in the second resonant scanning mode, the second frame (10) has a higher moment of inertia with respect to the moment of inertia of the first frame (6).

In one embodiment, the following relationship applies:

$${J}_{y y , 2} \geq 3 \cdot {J}_{y y , 1}$$

where J_{yy,1} indicates the moment of inertia of the first frame (6), of the mobile mass (2) and of the first and second torsional elements (8a, 8b) and J_{yy,2} indicates the moment of inertia of the second frame (10), around the second rotation axis (F.A.).

In one embodiment, in the second resonant scanning mode, the actuation transfer structure (20) is configured to rotate in phase with respect to the movement of the mobile mass (2) around the second rotation axis (F.A.) and in anti-phase with respect to the second frame (10); wherein the following relationship applies:

$${J}_{y y , 3} \geq 0.75 \cdot {J}_{y y , 2}$$

where J_{yy,3}, J_{yy,2} indicate the moments of inertia of the actuation structure (20) and, respectively, of the second frame (10) around the second rotation axis (F.A.).

In one embodiment, in the second resonant scanning mode, the actuation transfer structure (20) is configured to rotate in anti-phase with respect to the movement of the mobile mass (2) around the second rotation axis (F.A.) and in phase with respect to the second frame (10); wherein the following relationship applies:

$${J}_{y y , 3} < 0.75 \cdot {J}_{y y , 2}$$

where J_{yy,3}, J_{yy,2} indicate the moments of inertia of the actuation structure (20) and, respectively, of the second frame (10) around the second rotation axis (F.A.).

In one embodiment, the lower and higher resonance frequencies both have values higher than 10 kHz and a ratio between the higher and lower resonance frequencies is between 1.5 and 3.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A microelectromechanical mirror structure, comprising:
a mobile mass, configured to be actuated around a first rotation axis, with a first resonant scanning mode at a first resonance frequency around a second rotation axis, with a second resonant scanning mode at a second resonance frequency greater than the first resonance frequency;
a first frame suspended and surrounding the mobile mass and elastically coupled to the mobile mass by a first torsional elastic element and a second torsional elastic element aligned on opposite sides of the mobile mass along the second rotation axis;
a second frame suspended and arranged externally around the first frame and elastically coupled to the first frame by a third torsional elastic element and a fourth torsional elastic element aligned along the first rotation axis;
first piezoelectric actuators, arranged on the second frame and configured to actuate the first resonant scanning mode of the mobile mass; and
an actuation structure arranged externally to the second frame and carrying second piezoelectric actuators configured to actuate the second resonant scanning mode of the mobile mass.

2. The structure according to claim 1, wherein the actuation structure includes a first actuation arm and a second actuation arm arranged externally to the second frame on opposite sides of the second frame with respect to the second rotation axis. each of the first and second actuation arms having both ends coupled to anchors of the microelectromechanical mirror structure and carrying a respective pair of the second piezoelectric actuators.

3. The structure according to claim 1, further comprising an actuation transfer structure interposed between the actuation structure and the second frame and configured to transfer an actuation force generated by the second piezoelectric actuators to the second frame for actuating the second resonant scanning mode of the mobile mass. the actuation transfer structure being elastically coupled to the actuation structure by a first couple elastic element and a second coupling elastic element aligned at the first rotation axis.

4. The structure according to claim 3, wherein the actuation transfer structure includes a third frame, suspended and arranged externally to the second frame and coupled to the second frame by a fifth torsional elastic element and a sixth torsional elastic element extending aligned along the second rotation axis, between facing sides of the first and second frames on opposite sides of the mobile mass.

5. The structure according to claim 3, wherein the actuation transfer structure includes beam elements, suspended and placed externally to the second frame in pairs on opposite sides of the second frame; wherein the beam elements of each pair face a respective side of the second frame and have a first common end, arranged at the second rotation axis and coupled to the actuation structure by the first or second coupling elastic element, and a second end coupled to the respective side of the second frame, distally and on the opposite side with respect to the second rotation axis.

6. The structure according to claim 5, wherein the beam elements have an elongated shape with an aspect ratio greater than or equal to 4:1.

7. The structure according to claim 1, wherein the first frame has major sides including elongated elements with an aspect ratio greater than or equal to 6:1.

8. The structure according to claim 1, wherein, in the first resonant scanning mode, the second frame is integral with the actuation transfer structure in the rotation around the first rotation axis due to actuation of the first piezoelectric actuators, and the first frame is integral with the mobile mass in a rotation in anti-phase with respect to the second frame around the first rotation axis at the first resonance frequency.

9. The structure according to claim 1, wherein, in the first resonant scanning mode, the second frame and the actuation transfer structure jointly have, as a single rigid body, a higher moment of inertia with respect to the moment of inertia of the first frame.

10. The structure according to claim 9, wherein the following relationship applies:
$${J}_{xx , 2} + {J}_{xx , 3} \geq 3 \cdot {J}_{xx , 1}$$
where J_{xx,1} indicates the overall moment of inertia of the first frame, of the mobile mass, and of the first and second torsional elements, where J_{xx,2}, J_{xx,3} indicate the moments of inertia of the second frame and, respectively, of the actuation transfer structure, around the first rotation axis.

11. The structure according to claim 1, wherein, in the second resonant scanning mode, the first frame is configured to have a rotation movement around the second rotation axis, in anti-phase with respect to the movement of the second frame and in phase with the mobile mass; the first frame being configured to transfer a rotation torque from the second frame to the mobile mass for its rotation around the second rotation axis.

12. The structure according to claim 1, wherein, in the second resonant scanning mode, the second frame has a higher moment of inertia with respect to the moment of inertia of the first frame.

13. The structure according to claim 12, wherein the following relationship applies:
$${J}_{y y , 2} \geq 3 \cdot {J}_{y y , 1}$$
where J_{yy,1} indicates the moment of inertia of the first frame, of the mobile mass and of the first and second torsional elements and J_{yy,2} indicates the moment of inertia of the second frame, around the second rotation axis.

14. The structure according to claim 1, wherein in the second resonant scanning mode, the actuation transfer structure is configured to rotate in phase with respect to the movement of the mobile mass around the second rotation axis and in anti-phase with respect to the second frame; wherein the following relationship applies:
$${J}_{y y , 3} \geq 0.75 \cdot {J}_{y y , 2}$$
where J_{yy,3}, J_{yy,2} indicate the moments of inertia of the actuation structure and, respectively, of the second frame around the second rotation axis.

15. The structure according to claim 1, wherein in the second resonant scanning mode, the actuation transfer structure is configured to rotate in anti-phase with respect to the movement of the mobile mass around the second rotation axis and in phase with respect to the second frame; wherein the following relationship applies:
$${J}_{y y , 3} < 0.75 \cdot {J}_{y y , 2}$$
where J_{yy,3}, J_{yy,2} indicate the moments of inertia of the actuation structure and, respectively, of the second frame around the second rotation axis.

16. The structure according to claim 1, wherein the first and higher resonance frequencies both have values higher than 10 kHz and a ratio between the higher and first resonance frequencies is comprised between 1.5 and 3.

17. A method, comprising:
activating, with first piezoelectric actuators, a first resonant scanning mode of a mobile mass around a first axis, the mobile mass being surrounded by a first frame suspended and coupled to the mobile mass by a first torsional elastic element and a second torsional elastic element arranged along a second axis perpendicular to the first axis, a second frame suspended and surrounding the second frame and connected to the first frame by a third torsional elastic element and a fourth torsional elastic element arranged along the first axis, the first piezoelectric actuators being on the second frame; and
activating, with second piezoelectric actuators on an actuation structure arranged externally to the second frame, a second resonant scanning mode of the mobile mass around the second axis, wherein the first resonant scanning mode has a first scanning frequency and the second resonant scanning mode has a second scanning frequency higher than the first resonance frequency.

18. The method of claim 17, wherein the actuation structure includes a first actuation arm and a second actuation arm arranged externally to the second frame on opposite sides of the second frame with respect to the second rotation axis. each of the first and second actuation arms having both ends coupled to anchors of the microelectromechanical mirror structure and carrying a respective pair of the second piezoelectric actuators.

19. A device, comprising:
a suspended mobile mass having a mirror surface;
a suspended first frame surrounding the mobile mass and coupled to the mobile mass by first torsional elastic elements arranged along a first axis;
a suspended second frame surrounding the mobile mass and coupled to the mobile mass by second torsional elastic elements arranged along a second axis perpendicular to the first axis and including first piezoelectric actuators;
an actuation structure external to the second frame and including second piezoelectric actuators; and
an actuation transfer structure interposed between the actuation structure and the second frame.

20. The device of claim 19, comprising third torsional elastic elements coupled between the second frame and the actuation transfer structure and arranged along the first axis.
